(19) United States
(12) Patent Application Publication
(10) Pub. No.: US 2011/0133809 A1
(43) Pub. Date: Jun. 9, 2011

(54) Semiconductor device and method for cancelling offset voltage of sense amplifier

(75) Inventors: Ankur Goel, Bangalore (IN); Eswararao Potladhurthi, Bangalore (IN)

(73) Assignee: Elpida Memory, Inc., Tokyo (JP)

(21) Appl. No.: 12/591,884

(22) Filed: Dec. 3, 2009

(51) Int. Cl. H03L 5/00

(52) U.S. Cl. 327/307

(57) ABSTRACT

A semiconductor device includes first and second signal lines; a sense amplifier amplifying potential difference occurring in the first and second signal lines; a cancel charge generator circuit producing cancel charge that corresponds to offset voltage in the sense amplifier; a cancel charge storage circuit storing the cancel charge; and a cancel charge feed circuit feeding the cancel charge that has been stored in the cancel charge storage circuit to the first and second signal lines to cancel the offset voltage.

### BACKGROUND OF THE INVENTION

1. Field of the Invention

The present invention relates to a semiconductor device, and particularly relates to a semiconductor device equipped with a sense amplifier. The present invention also relates to a method for cancelling the offset voltage of a sense amplifier.

2. Description of Related Art

DRAM (Dynamic Random Access Memory), a typical semiconductor memory device, produces a small potential difference in a pair of bit lines based on data stored in a memory cell, and this potential difference is amplified by a sense amplifier to allow the data to be read. The potential difference which shows up in the pair of bit lines is very small when the data is read, and sense amplifiers are therefore designed with high sensitivity to allow the small potential difference to be properly amplified.

However, structural variability or the like in sense amplifiers inevitably results in offset voltage, which can therefore lower the sensing margin. Offset voltage occurring in sense amplifiers is the same situation as when a predetermined potential difference occurs due to differences in the ability of the transistors that constitute the sense amplifier despite the fact that the potential of the pair of bit lines is actually the same. The “predetermined potential difference” is referred to as an offset voltage.

The methods for cancelling the offset voltage of a sense amplifier are described in Takayuki Kawahara, Takeshi Sakata, Kiyooltoh, Yoshiki Kawajiri, TakesadaAkiba, GoroKitsukawa, and Masakazu Aoki, A High-speed, Small-Area, Threshold-Voltage-Mismatch Compensation Sense Amplifier for Gigabit-Scale DRAM Arrays, IEEE JOURNAL OF SOLID-STATE CIRCUITS, VOL. 28, NO. 7, JULY 1993; Yohji Watanabe, Nobuo Nakamura, and Shigeyoshi Watanabe, Offset Compensating Bit-Line sensing Scheme for High Density DRAM's; and SHUNICHI SUZUKI AND MASAKI HIRATA, Threshold Difference Compensated Sense Amplifier, IEEE JSSC, 1979.

### SUMMARY

However, a problem with the methods described in the above documents is that the complex circuit structure for cancelling offset voltage results in greater chip surface area. Also, the problem of offset voltage in sense amplifiers is not limited to DRAM but is a problem shared by all semiconductor memory with sense amplifiers.

The present invention seeks to solve one or more of the above problems, or to improve upon those problems at least in part.

In one embodiment, there is provided a semiconductor device that includes first and second signal lines; a sense amplifier amplifying potential difference occurring in the first and second signal lines; a cancel charge generator circuit producing cancel charge that corresponds to offset voltage in the sense amplifier; a cancel charge storage circuit storing the cancel charge; and a cancel charge feed circuit feeding the cancel charge that has been stored in the cancel charge storage circuit to the first and second signal lines to cancel the offset voltage.

In another embodiment, there is provided a method for cancelling the offset voltage of a sense amplifier that includes producing cancel charge according to the offset voltage in the sense amplifier to store the cancel charge; and feeding the stored cancel charge to the first and second signal lines to cancel the offset voltage.

According to the present invention, a cancel charge that corresponds to the offset voltage is temporarily stored and is fed to the first and second signal lines to thereby cancel offset voltage. The offset voltage can therefore be cancelled using a simple circuit structure.

### BRIEF DESCRIPTION OF THE DRAWINGS

The above features and advantages of the present invention will be more apparent from the following description of certain preferred embodiments taken in conjunction with the accompanying drawings, in which:

FIG. 1 is a block diagram showing an outline of a semiconductor device according to a first preferred embodiment of the present invention;

FIG. 2 is a circuit diagram showing in greater detail the main parts of the semiconductor device in the first embodiment;

FIGS. 3A to 3C are diagrams showing different variations on a capacitative element C1;

FIG. 4 a timing chart illustrating the operation of the semiconductor device according to the first embodiment.

FIG. 5 is a diagram showing simulation results indicating the effects of the first embodiment;

FIG. 6 is a diagram showing other simulation results indicating the effects of the first embodiment;

FIG. 7 is a circuit diagram of a modification in which the timing signal φ2 is omitted by using timing signals φ1 and φ2 in common;

FIG. 8 is a timing chart showing the operation of the circuit shown in FIG. 7;

FIG. 9 is a circuit diagram showing the main parts of a semiconductor device according to a preferred second embodiment of the present invention;

FIG. 10 is a timing chart for illustrating the operation of the semiconductor device in the second embodiment;

FIG. 11 is a circuit diagram showing the main parts of a semiconductor device according to a preferred third embodiment of the present invention;

FIG. 12 is a timing chart for illustrating the operation of the semiconductor device in the third embodiment;

FIG. 13 is a diagram showing simulation results indicating the effects of the third embodiment; and

FIG. 14 is a diagram showing other simulation results indicating the effects of the third embodiment.

### DESCRIPTION OF THE PREFERRED EMBODIMENTS

It is apparent that the present invention is not limited to the above embodiments, but may be modified and changed without departing from the scope and spirit of the invention.

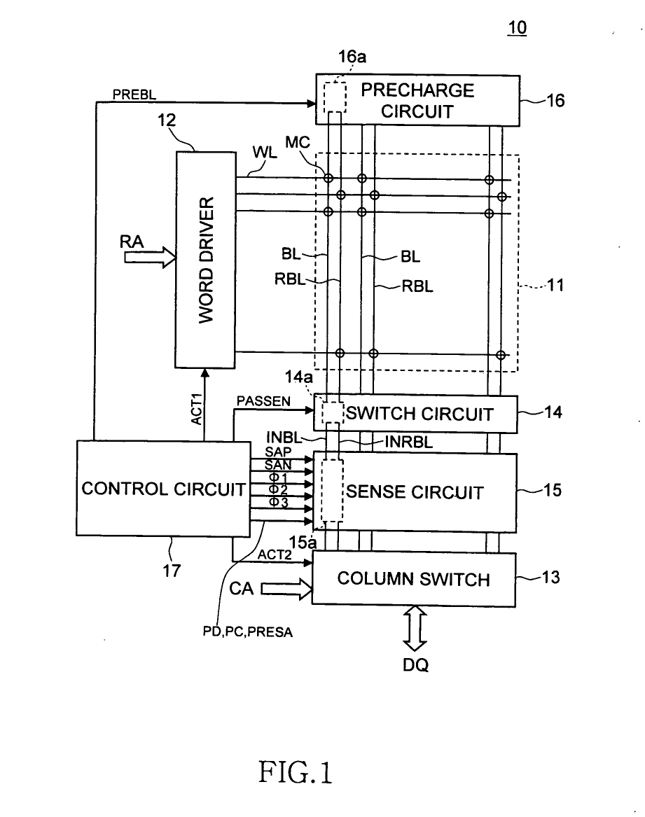

FIG. 1 is a block diagram showing an outline of a semiconductor device according to a first preferred embodiment of the present invention. The present embodiment illustrates a preferred example of the present invention in a DRAM application.

As shown in FIG. 1, the semiconductor memory 10 in the present embodiment has a memory cell array 11 comprising a plurality of memory cells MC, a word driver 12 for activating any of a plurality of word lines WL, and a column switch 13 for selecting any of a plurality of pairs of bit lines BL and RBL. The plurality of word lines WL and plurality of pairs of bit lines BL and RBL intersect in the memory array 11, with memory cells MC arranged at the intersecting points. Word lines WL are selected by the word driver 12 based on row address RA, and pairs of bit lines BL and RBL are selected by the column switch 13 based on column address CA. Data DQ is input/output to/from the pairs of bit lines BL and RBL selected by the column switch 13.

The pairs of bit lines BL and RBL are complementary signal lines and are connected to the sense circuit 15 through the switch circuit 14. In this Specification, the pairs of bit lines BL and RBL on the sense circuit 15 side as viewed from the switch circuit 14 may sometimes be referred to as the “signal lines INBL and INBRBL”. A bit line precharge circuit 16 is also connected to the pairs of bit lines BL and RBL. Various control signals produced by a control circuit 17 are supplied to the switch circuit 14, sense circuit 15, and bit line precharge circuit 16.

The switch circuit 14, sense circuit 15, and bit line precharge circuit 16 comprise unit circuits 14a, 15a, and 16a, respectively, provided for each pair of bit lines BL and RBL. The circuit structure and operation will be described in detail below, with a focus on unit circuits 14a, 15a, and 16a corresponding to predetermined pairs of bit lines BL and RBL.

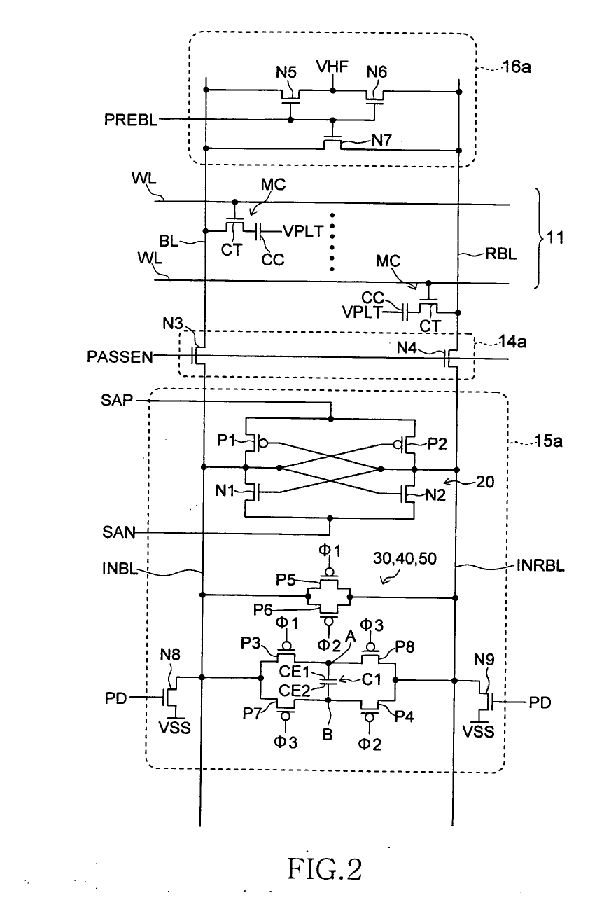

FIG. 2 is a circuit diagram showing in greater detail the main parts of the semiconductor device in the present embodiment.

As shown in FIG. 2, each of the memory cells MC that constitute the memory cell array 11 has a structure in which cell transistor CT and cell capacitor CC are serially connected between bit line BL or RBL and a plate electrode VPLT. The cell transistor CT is formed by N channel MOS transistor, and a gate electrode is connected to the corresponding word line WL. In this structure, when any of the word lines WL is activated to a high level, the corresponding cell transistor CT is turned on, and a cell capacitor CC and bit line BL or RBL are connected. The potential of the bit line BL or RBL thus changes according to the contents held in the cell capacitor CC.

One end of pair of the bit lines BL and RBL is connected to the pair of signal lines INBL and INRBL through the unit circuit 14a included in the switch circuit 14, and the other end is connected to the unit circuit 16a included in the bit line precharge circuit 16.

The unit circuit 14a of the switch circuit 14 comprises N channel MOS transistors N3 and N4 connected between the pair of bit lines BL and RBL and the pair of signal lines INBL and INRBL, respectively. A pass signal PASSEN from the control circuit 17 is commonly supplied to the gate electrodes of the N channel MOS transistors N3 and N4. Thus, when the pass signal PASSEN is activated to a high level, the pair of bit lines BL and RBL and the pairs of signal line INBL and INRBL are short circuited. By contrast, when the pass signal PASSEN is at a low level, the pair of bit lines BL and RBL and the pair of signal lines INBL and INRBL are cut off, and the parasitic capacitance of the bit lines BL and RBL therefore disappears from the sense amplifier 20.

The bit line precharge circuit 16 is a circuit for precharging the bit lines BL and RBL to an intermediate potential, and the unit circuit 16a comprises N channel MOS transistors N5 through N7. As shown in FIG. 2, the transistor N5 is connected between the intermediate potential VHF and a bit line BL, the transistor N6 is connected between the intermediate potential VHF and a bit line RBL, and the transistor N7 is connected between the bit line BL and the bit line RBL. A precharge signal PREBL is commonly supplied to the gate electrodes of the transistors N5 through N7. Thus, when the precharge signal PREBL is activated to a high level, the bit lines BL and RBL are precharged to the intermediate potential VHF. The intermediate potential VHF is set to an intermediate level between an active level (VDA) of the sense amplifier active signal SAP and an active level (VSS) of the sense amplifier active signal SAN.

As shown in FIG. 2, the sense amplifier 20, cancel charge generator circuit 30, cancel charge storage circuit 40, and cancel charge feed circuit 50 are included in the unit circuit 15a of the sense circuit 15.

The sense amplifier 20 is a circuit for amplifying the potential difference occurring in the signal lines INBL and INRBL, and has what is referred to as a flip flop structure. Specifically, the amplifier comprises pull-up transistors P1 and P2 for pulling up the signal lines INBL and INRBL, respectively, and pull-down transistors N1 and N2 for pulling down the signal lines INBL and INRBL, respectively, the transistors being cross coupled. Each of the pull-up transistors P1 and P2 consists of P channel MOS transistors, and each of the pull-down transistors N1 and N2 consists of N channel MOS transistors. The pull-up transistor P1 and pull-down transistor N1 for driving the signal line INBL constitute a first drive circuit unit, and the gate electrodes are commonly connected to the signal line INRBL. Similarly, the pull-up transistor P2 and pull-down transistor N2 for driving the signal line INRBL constitute a second drive circuit unit, and the gate electrodes are commonly connected to the signal line INBL.

The sense amplifier active signal SAP is supplied to the sources of the pull-up transistors P1 and P2. Therefore, when the sense amplifier active signal SAP is activated to a high level, operating voltage is supplied to the pull-up transistors P1 and P2, enabling pull up. On the other hand, the sense amplifier active signal SAN is supplied to the sources of the pull-down transistors N1 and N2. Therefore, when the sense amplifier active signal SAN is activated to a low level, operating voltage is supplied to the pull-down transistors N1 and N2, enabling pull down.

The cancel charge generator circuit 30 is a circuit for producing a cancel charge that corresponds to the offset voltage in the sense amplifier 20. The offset of the sense amplifier 20 is an imbalance that occurs as a result of manufacturing variability and the like. The offset occurring in the sense amplifier 20 is the same situation as when a predetermined potential difference occurs due to differences in the ability of the transistors that constitute the sense amplifier 20 despite the fact that the potential of the pairs of signal lines INBL and INRBL is actually the same. As already described, this predetermined potential difference is offset voltage.

The cancel charge generator circuit 30 of the present embodiment senses offset voltage on the basis of differences in ability between the pull-up transistor P1 included in the first drive circuit unit and the pull-up transistor P2 included in the second drive circuit unit, and on that basis produces a cancel charge. In the present embodiment, a difference in ability between the pull-up transistors is considered to be a problem. The reason is that a case in which a difference in ability between the pull-up transistors is more susceptible to variability than a difference in ability between the pull-down transistors is assumed. A case in which a difference in ability between pull-down transistors is more susceptible to variability than a difference in ability between pull-up transistors will be discussed in a separate embodiment.

The cancel charge generator circuit 30 comprises a cancel charge input transistor P3 for connecting the signal line INBL and a node A, a chance charge input transistor P4 for connecting the signal line INRBL and a node B, equalizing transistors P5 and P6 for short circuiting the signal line INBL and signal line INRBL, and pre-discharge transistors N8 and N9 for pre-discharging the signal lines INBL and INRBL, respectively. Of these, the transistors P3 through P6 are P channel MOS transistors, and the transistors N8 and N9 are N channel MOS transistors.

A timing signal φ1 is commonly supplied to the gate electrodes of the transistors P3 and P5. Thus, when the timing signal φ1 is activated to a low level, the signal line INBL is connected to the node A, and the signal line INBL and signal line INRBL are short circuited. Similarly, a timing signal φ2 is commonly supplied to the gate electrodes of the transistors P4 and P6. When the timing signal φ2 is activated to a low level, the signal line INRBL is thereby connected to the node B, and the signal line INBL and signal line INRBL are short circuited.

A pre-discharge signal PD is commonly supplied to the transistors N8 and N9. When the pre-discharge signal PD is activated to a high level, the signal lines INBL and INRBL are thereby discharged.

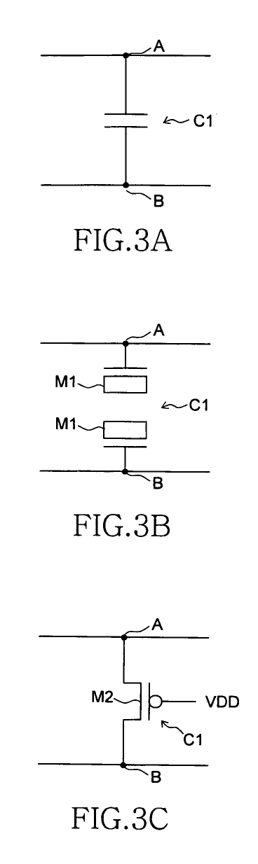

The cancel charge storage circuit 40 is a circuit for storing the cancel charge, and the circuit comprises a capacitative element C1 connected between the nodes A and B. That is, the capacitative element C1 has a first electrode CE1 and a second electrode CE2, wherein the first electrode CE1 is connected to the node A, and the second electrode CE2 is connected to the node B. The circuit structure of the capacitative element C1 may be a usual capacitative element as shown in FIG. 3(a), the gate capacitance of a depression type of MOS transistor M1 as shown in FIG. 3(b), or the capacitance between the source and drain of a MOS transistor M2 as shown in FIG. 3(c). In the example shown in FIG. 3(c), a P channel MOS transistor M2 is used, and the gate electrode is fixed to the power source potential VDD, so as to always be off.

The cancel charge feed circuit 50 is a circuit for feeding the cancel charge to the signal lines INBL and INRBL, and the circuit comprises a cancel charge output transistor P7 for connecting the signal line INBL and the node B, and a cancel charge output transistor P8 for connecting the signal line INRBL and the node A. These transistors P7 and P8 are P channel MOS transistors. A timing signal φ3 is commonly supplied to the gate electrodes of the transistors P7 and P8. When the timing signal φ3 is activated to a low level, the signal line INBL is thereby connected to the node B, and the signal line INRBL is connected to the node A.

The above is a circuit diagram of the main parts of the semiconductor device according to the present embodiment. The operation of the semiconductor device according to the present embodiment is described below.

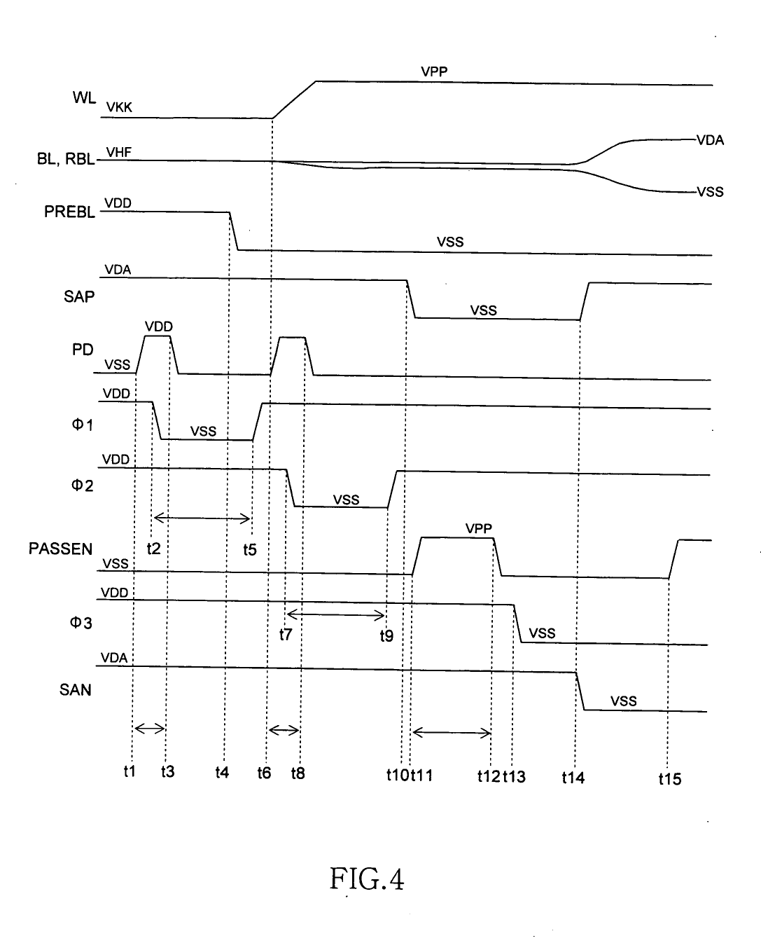

FIG. 4 is a timing chart illustrating the operation of the semiconductor device according to the present embodiment. Times t1 through t15 in the following description are times passing in sequence, as shown in FIG. 4.

First, in the state before time t1, the pass signal PASSEN is at a low level (VSS), and the bit line precharge signal PREBL is at a high level (VDD). The pair of bit lines BL and RBL and the pair of signal lines INBL and INRBL are thus cut off by the switch circuit 14, and the pair of bit lines BL and RBL is precharged to an intermediate potential VHF by the bit line precharge circuit 16. During this period, the sense amplifier active signal SAP is activated to a high level (VDA), and operating voltage is therefore supplied to the pull-up transistors P1 and P2 included in the sense amplifier 20. Thus, the level of the signal line INBL becomes a level which is gained by subtracting the threshold voltage Vtp1 of the pull-up transistor P1 from the power source potential VDA, and the level of the signal line INRBL becomes a level which is gained by subtracting the threshold voltage Vtp2 of the pull-up transistor P2 from the power source potential VDA. Although the threshold voltage Vtp1 and the threshold voltage Vtp2 are designed to be at the same level, they are not entirely the same due to manufacturing variability, and the difference results in an offset in the sense amplifier 20.

Because the sense amplifier active signal SAN is also inactive during this period, the sense amplifier 20 is incapable of pull-down operation. That is, the sense amplifier 20 is still inactive, enabling only pull-up operation.

The pre-discharge signal PD is then activated in the period from time t1 to t3. The pair of signal lines INBL and INRBL is thereby temporarily discharged. The temporary discharge level of the pair of signal lines INBL and INRBL does not need to be lowered to the power source potential VSS (power source on the low end), and it is, sufficient for this level to be lowered at least a level which is gained by subtracting a value being greater than the threshold potentials Vtp1 and Vtp2 of the pull-up transistors P1 and P2 from the power source potential VDS (power source on the high end). Because the pass signal PASSEN is at a low level at this point in time as described above, the pair of bit lines BL and RBL remains precharged.

When the pair of signal lines INBL and INRBL is discharged, the timing signal φ1 is activated in the period from time t2 to t5. When the timing signal φ1 is activated, the transistors P3 and P5 that constitute the cancel charge generator circuit 30 are turned on. When the transistor P5 is turned on, the pair of signal lines INBL and INRBL is short circuited, and a state therefore results in which the gate and drain of the pull-up transistor P1 are short circuited. That is, the pull-up transistor P1 is diode-connected. Therefore, after the precharge transistor N8 is turned off, the signal line INBL increases from the discharge level toward a level which is gained by subtracting the threshold voltage Vtp1 of the pull-up transistor P1 from the power source potential VDA (VDA−Vtp1). The rate of increase depends on the ability of the pull-up transistor P1. Therefore, at time t5 after a certain period of time has passed, when the timing signal φ1 is inactivated to turn the transistor p3 from on to off, a predetermined level of charge, that is, the cancel charge produced on the signal line INBL side, is stored in the node A.

The similar operations are performed on the signal line INRBL side. That is, the pre-discharge signal PD is activated in the period from time t6 to t8, and the timing signal φ2 is activated in the period from time t7 to t9. When the timing signal φ2 is activated, the transistors P4 and P6 that constitute the cancel charge generator circuit 30 are turned on. The pull-up transistor P2 is thereby brought to a state of a diode connection. Therefore, after the precharge transistor N9 is turned off, the signal line INRBL increases from discharge level toward a level which is gained by subtracting the threshold voltage Vtp2 of the pull-up transistor P2 from the power source potential VDA (VDA−Vtp2). The rate of increase depends on the ability of the pull-up transistor P2. Therefore, at time t9 after a certain period of time has passed, when the timing signal φ2 is inactivated to turn the transistor P4 from on to off, a predetermined level of charge, that is, the cancel charge produced on the signal line INRBL side, is stored in the node B.

In this way, the cancel charge produced on the signal line INBL side is stored in the first electrode CE1 of the capacitative element C1 that constitutes the cancel charge storage circuit 40, and the cancel charge produced on the signal line INRBL side is stored in the second electrode CE2.

While the cancel charge is being produced, the bit line precharge signal PREBL is inactivated, and a predetermined word line WL is then changed from the inactive level VKK (<VSS) to the active level VPP (>VDA). A memory cell MC corresponding to the selected world line WL is thereby connected to the bit line BL or RBL, and the potential changes according to the stored content. The control circuit 17 supplies an activation signal ACT1 to the word driver 12 to activate the word line WL. In the example shown in FIG. 4, the bit line precharge signal PREBL is inactivated at time t4, and the word line WL is activated at time t6, but these timings are not limited to this option alone. The production of cancel charge and the selection of memory cell MC can thus be accomplished in parallel. This is because the pair of bit lines BL and RBL and the pair of signal lines INBL and INRBL are separated by the switch circuit 14.

Upon the completion of the cancel charge production and the reading of data from the memory cell MC, the sense amplifier active signal SAP is temporarily inactivated at time t10, and the pass signal PASSEN is again activated in the period from time t11 to t12. The active level of the pass signal PASSEN is VPP. The pair of bit lines BL and RBL and the pair of signal lines INBL and INRBL are thereby short circuited, and the charge that is read from the memory cell MC is fed to the sense amplifier 20. During this period the sense amplifier 20 does not perform any sensing operations because the sense amplifier active signals SAP and SAN are both inactivated.

The timing signal φ3 is then activated at time t13. The transistors P7 and P8 that constitute the cancel charge feed circuit 50 are thereby turned on, the node B is connected to the signal line INBL, and the node A is connected to the signal line INRBL. In other words, the cancel charge produced in either of the pair of signal lines INBL or INRBL is supplied to the other side. The offset in the sense amplifier 20 caused by differences between the ability of the pull-up transistors P1 and P2 is thereby cancelled.

Subsequently activating the sense amplifier active signals SAP and SAN at time t14 causes the sense amplifier 20 to be activated and an amplification operation to be performed according to the potential difference occurring in the pair of signal lines INBL and INRBL. Because the sense amplifier 20 is thus activated in a state in which the offset voltage is cancelled in advance, the sensing margin is dramatically increased. When the pass signal PASSEN is then activated again at time t15, the signal amplified by the sense amplifier 20 is restored in the memory cell MC.

The control circuit 17 then supplies an activation signal ACT2 to the column switch 13, and the pair of signal lines INBL and INRBL is thereby selected based on the column address CA.

Thus, in the present embodiment, offset caused by differences in ability between the pull-up transistors P1 and P2 of the sense amplifier 20 is sensed and cancel charge is produced, and the charge is fed to the signal line on the opposite side to cancel the offset. It is therefore possible to effectively cancel offset in the sense amplifier 20 even in case where the difference in ability between pull-up transistors is more susceptible to variation than difference in ability between pull-down transistors.

Furthermore, because the input of cancel charge to the node A and the input of cancel charge to the node B are done separately, the input of cancel charge to one is less likely to affect cancel charge in the other, making it possible to properly input the respective cancel charge.

The present embodiment is also provided with transistors N3 and N4 for cutting off the pair of bit lines BL and RBL and the pair of signal lines INBL and INRBL, and therefore allows cancel charge to be produced in parallel with bit line precharging or word line activation. Since, furthermore, the parasitic capacitance of the bit lines BL and RBL disappears from the sense amplifier 20 while the transistors N3 and N4 are off, the cancel charge can be produced at a higher rate.

Since the cancel charge is produced dynamically in the present embodiment, the cancel charge level will change not only on the basis of the capacitance of the capacitative element C1, but also on the basis of the activation time of the pre-discharge signal PD, the ability of the precharge transistors N8 and N9, the activation times of the timing signals φ1 and φ2, and the like. These parameters are therefore preferably set to the optimal values to ensure that the offset voltage is more accurately cancelled.

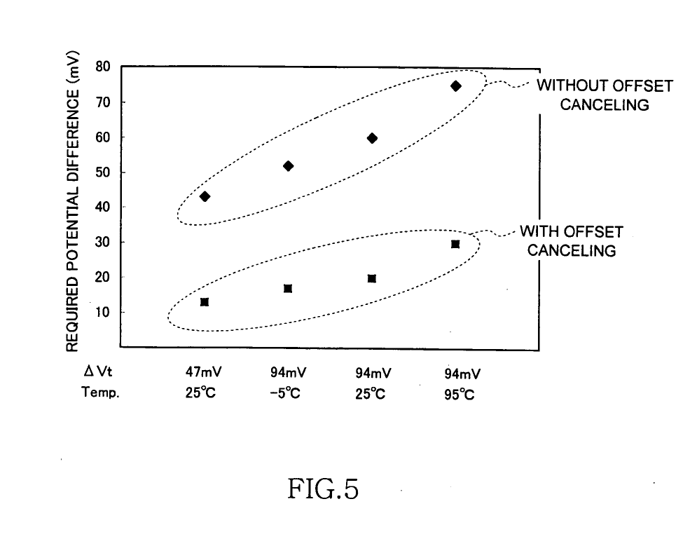

FIG. 5 comprises simulation results showing the effects of the present embodiment. Along the horizontal axis in FIG. 5, “ΔVt” shows the offset voltage of the sense amplifier 20, and “Temp.” shows the ambient temperature. The vertical axis in FIG. 5 is the potential difference necessary for proper sensing operations (required potential difference). The various parameters such as the capacitance of the capacitative element C1 were optimized assuming that the pull-up transistors P1 and P2 have a threshold voltage difference of 40 mV and that the pull-down transistors N1 and N2 have a threshold voltage difference of 20 mV.

As shown in FIG. 5, it may be seen that, in either case, the necessary potential differences decreases dramatically when the offset voltage is cancelled. Specifically, in Case 1 (ΔVt=47 mV, temperature 25° C.), the required potential difference decreases 30 mV as a result of the offset voltage being cancelled. In Cases 2 to 4, the simulation results are shown for ΔVt=94 mV and a temperature of −5° C., 25° C., and 95° C., respectively, where the required potential difference is decreased 35 mV, 40 mV, and 45 mV, respectively. As shown in FIG. 5, when the ΔVt is greater or the ambient temperature is higher, the required potential difference tends to be greater and the sensing margin tends to decrease. However, when the offset voltage is cancelled as in the present embodiment, proper sensing can be preserved because offset voltage is cancelled to a greater extent the greater the decrease in the sensing margin.

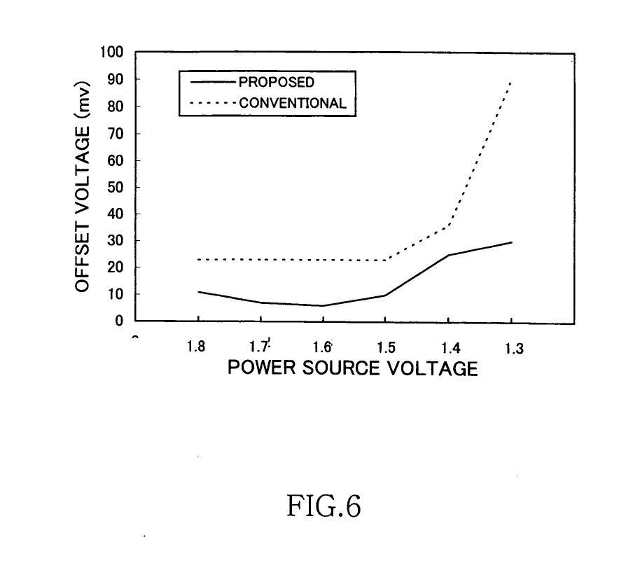

FIG. 6 comprises other simulation results showing the effects of the present embodiment, and shows the relationship between power source voltage and offset voltage. The conditions were kept the same as in the simulation shown in FIG. 5.

As shown in FIG. 6, when the offset voltage is not cancelled (CONVENTIONAL), it may be seen that the offset voltage is greater the lower the power source voltage. By contrast, when the offset voltage is cancelled as in the present embodiment (PROPOSED), the offset voltage is completely reduced, and the dependency on the power source voltage is far lower. Proper sensing can thus be preserved even when the power source voltage is low.

In the above embodiment, the timing signals φ1 and φ2 are separate from each other, but they can be shared signals also.

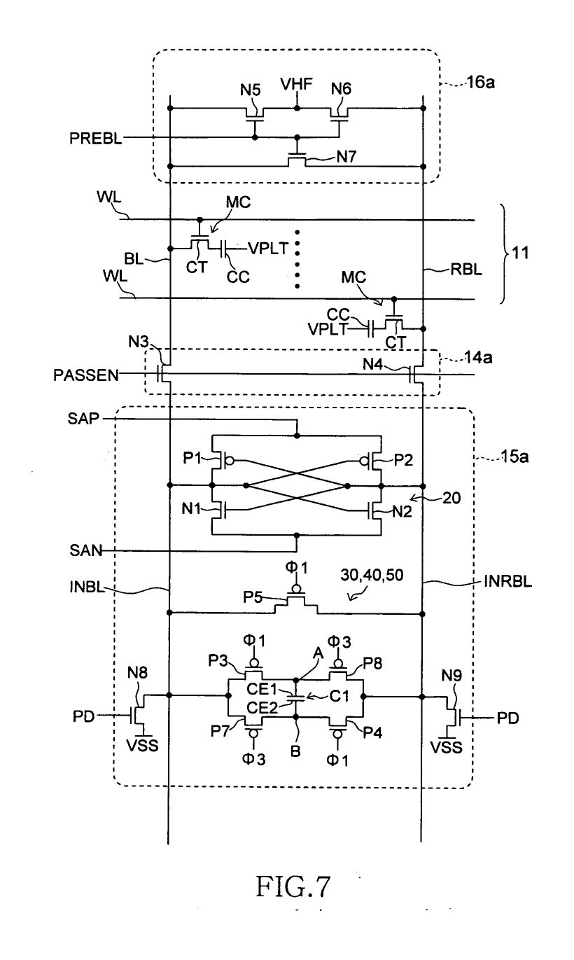

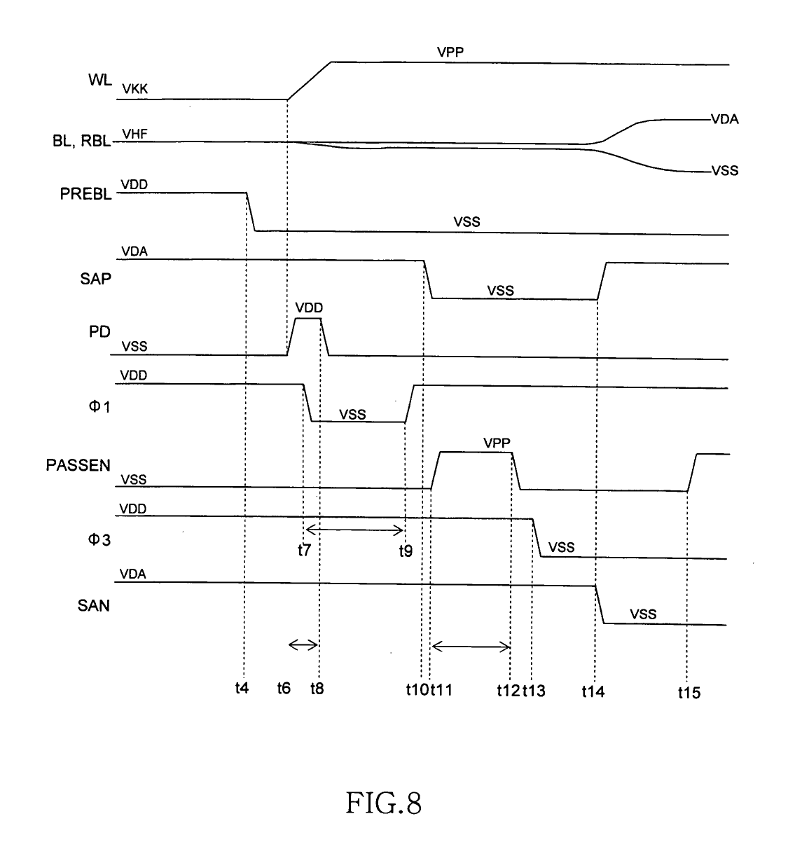

FIG. 7 is a circuit diagram of a modification in which the timing signal φ2 is omitted by using timing signals φ1 and φ2 in common. FIG. 8 is a timing chart showing the operation of the circuit shown in FIG. 7.

In the modification shown in FIG. 7, the transistor P6 is omitted, and the timing signal φ1 is supplied to the gate electrode of the transistor P4. Since the embodiment is otherwise the same as the above embodiment, the same elements will be indicated by the same symbols, without further elaboration. As shown in FIG. 8, the pre-discharge signal PD is activated only once in this modification because the timing signal φ2 has been left out. That is, cancel charge is produced simultaneously in the signal lines INBL and INRBL through the activation of one pre-discharge signal PD and one timing signal φ1, and the charge is simultaneously stored in the capacitative element C1.

In the modification shown in FIGS. 7 and 8, offset voltage can be cancelled at a high rate because the cancel charge is input to the node A simultaneously with the cancel charge input to the node B.

A second embodiment of the present invention is described below. The second embodiment is an embodiment capable of cancelling offset voltage caused by differences in ability between the pull-down transistors that constitute the sense amplifier.

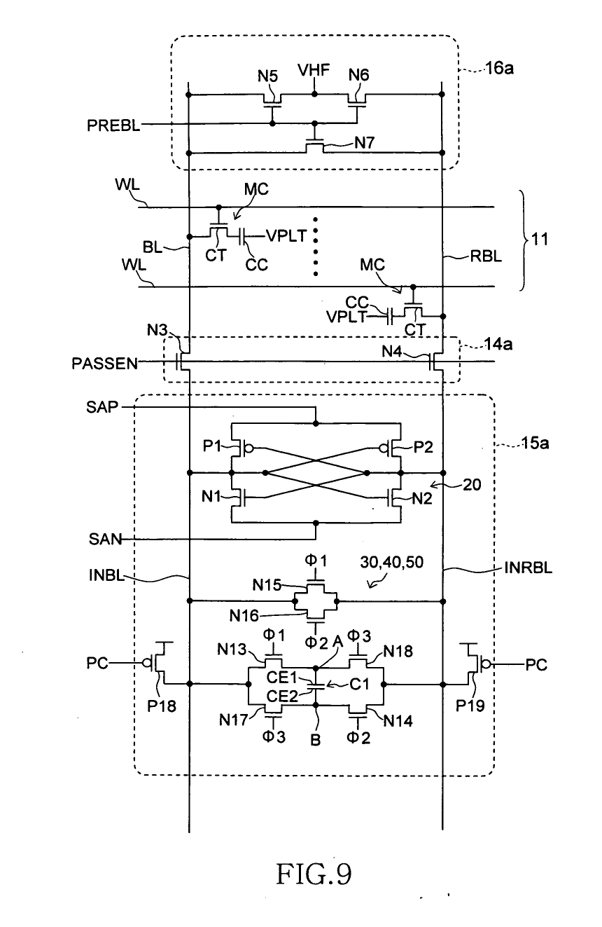

FIG. 9 is a circuit diagram showing the main parts of a semiconductor device according to a preferred second embodiment of the present invention.

As shown in FIG. 9, the semiconductor device of the present embodiment is different from the first embodiment above in that the P channel MOS transistors P3 through P8 used in the first embodiment described above are replaced by N channel MOS transistors N13 through N18, and the pre-discharge transistors N8 and N9 are replaced by precharge transistors P18 and P19. In accordance with this arrangement, the polarity of the timing signals φ1 through φ3 is the opposite of that in the first embodiment, and a precharge signal PC in which the polarity is reversed is used instead of the pre-discharge signal PD. Since the present embodiment is otherwise the same as the first embodiment described above, the same parts will be indicated by the same symbols, without further elaboration.

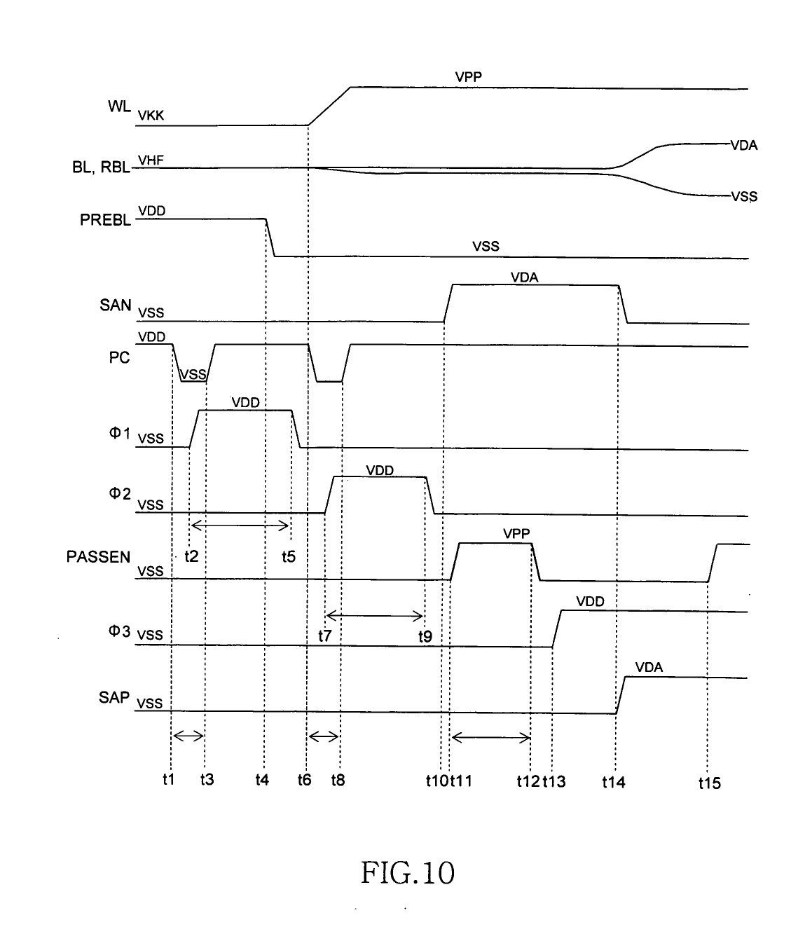

FIG. 10 is a timing chart for illustrating the operation of the semiconductor device in the present embodiment.

As shown in FIG. 10, the operation of the semiconductor device in the present embodiment is the same as that in the first embodiment except that the activation of the sense amplifier active signals SAP and SAN is the reverse of the waveform in the timing chart shown in FIG. 4. That is, during the period from time t1 to t3 and t6 to t8, the precharge signal PC is activated, whereby the pairs of signal lines INBL and INRBL are temporarily precharged, the timing signal φ1 is then activated in the period from time t2 to t5, and the timing signal φ2 is activated during the period from time t7 to t9. The signal line INBL is thereby reduced toward a level (VSS+Vtn1) which is gained by adding the threshold voltage Vtn1 of the pull-up transistor N1 to the power source potential VSS, and the signal line INRBL is reduced toward a level (VSS+Vtn2) which is gained by adding the threshold voltage Vtn2 of the pull-down transistor N2 to the power source potential VSS. Because the rate of decrease depends on the ability of the pull-down transistors N1 and N2, cancel charge is stored in the nodes A and B, respectively, when the timing signals φ1 and φ2 are inactivated at predetermined times t5 and t9.

Cancel charge stored in this manner are fed to the other signal line through the activation of the timing signal φ3 at time t13 and the actuation of the transistors N17 and N18 in the same manner as in the first embodiment. The offset in the sense amplifier 20 caused by differences in ability between the pull-down transistors N1 and N2 is thereby cancelled.

Thus, in the present embodiment, offset caused by differences in ability between the pull-down transistors N1 and N2 of the sense amplifier 20 is detected and cancel charge is produced, and the charge is fed to the signal line on the opposite side to cancel the offset. It is therefore possible to effectively cancel offset in the sense amplifier 20 even in cases where the differences in ability between pull-down transistors is more susceptible to variation than differences in ability between pull-up transistors.

Since the cancel charge is produced dynamically in the present embodiment, the cancel charge level will change not only on the basis of the capacitance of the capacitative element C1, but also on the basis of the activation time of the precharge signal PC, the ability of precharge transistors P18 and P19, the activation time of the timing signals φ1 and φ2, and the like. These parameters are therefore preferably set to the optimal values to ensure that the offset potential difference is more accurately cancelled.

In the present embodiment, the timing signal φ2 can also be omitted by using timing signals φ1 and φ2 in common.

A third embodiment of the present invention is described below. The third embodiment is an embodiment capable of cancelling the overall offset voltage of the sense amplifier.

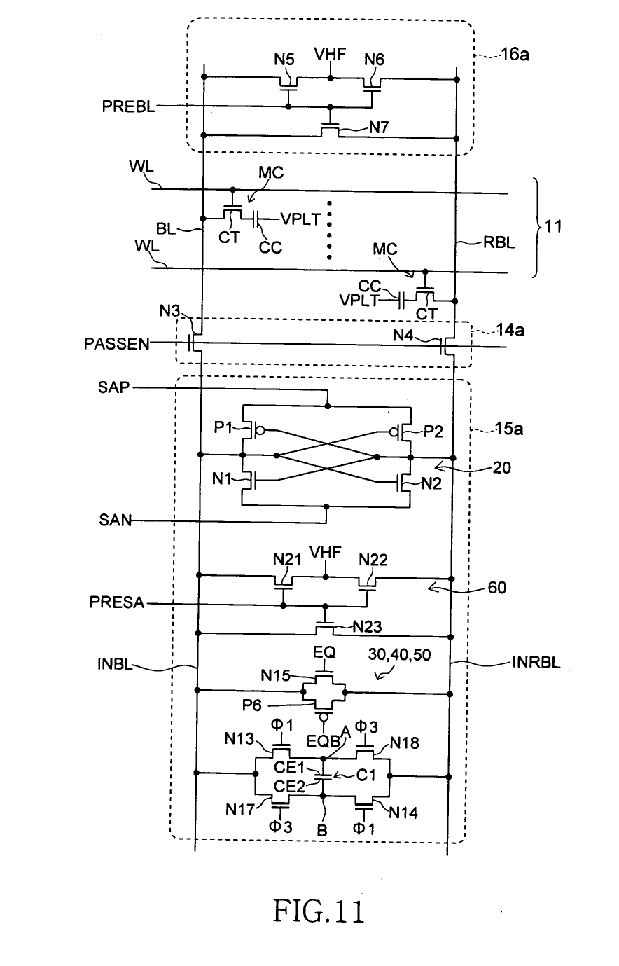

FIG. 11 is a circuit diagram showing the main parts of the semiconductor device according to a third embodiment of the present invention.

As shown in FIG. 11, the semiconductor device in the present embodiment is different from the second embodiment above in that the N channel MOS transistor N16 used in the second embodiment described above is replaced by a P channel MOS transistor P6, a sense amplifier precharge circuit 60 is added, and the precharge transistors P18 and P19 are omitted. Since the circuit structure is otherwise the same as in the second embodiment described above, the same parts will be indicated by the same symbols, without further elaboration.

The sense amplifier precharge circuit 60 is a circuit for precharging the pairs of signal lines INBL and INRBL to an intermediate potential VHF, and has a circuit structure similar to the unit circuit 16a of the bit line precharge circuit 16. Specifically, the circuit comprises N channel MOS transistors N21 through N23, where the transistor N21 is connected between the intermediate potential VHF and the signal line INBL, the transistor N22 is connected between the intermediate potential VHF and the signal line INRBL, and the transistor N23 is connected between the signal line INBL and signal line INRBL. A precharge signal PRESA is commonly supplied to the gate electrodes of the transistors N21 through N23. The signal lines INBL and INRBL are thereby precharged to the intermediate potential VHF when the precharge signal PRESA is activated to a high level (VDD).

In the present embodiment, the parallel circuit of the P channel MOS transistor P6 and the N channel MOS transistor N15 are used as equalizing transistors that form the cancel charge generator circuit 30. This is to minimize disjunction between the offset voltage and the cancel voltage in cases where the threshold values of both the P channel MOS transistor and N channel MOS transistor are variable. For the transistor P6 in particular, the threshold voltage is preferably designed to be the same as that of the pull-up transistors P1 and P2 that constitute the sense amplifier 20, and the transistor N15 is also preferably designed with the same threshold voltage as that of the pull-down transistors N1 and N2 that constitute the sense amplifier 20. This allows any disjunction between the offset voltage and the cancel voltage to be minimized, and enables extremely accurate offset cancellation.

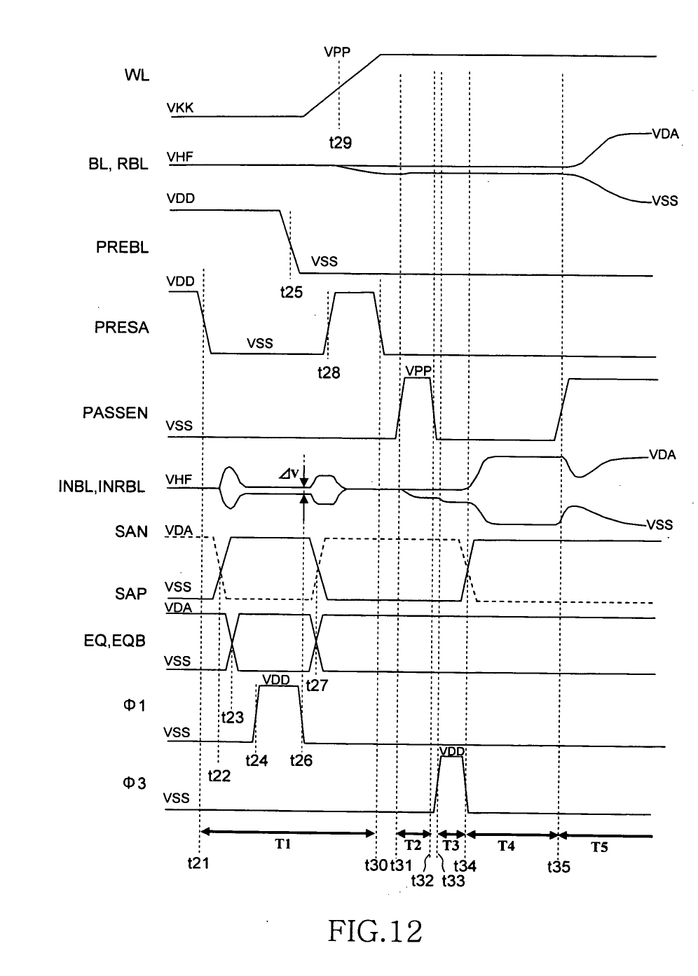

FIG. 12 is a timing chart illustrating the operation of the semiconductor device according to the present embodiment. Times t21 through t35 in the following description are times passing in sequence, as shown in FIG. 12.

First, prior to time t21, the pass signal PASSEN is at a low level (VSS), and the bit line precharge signal PREBL and sense amplifier precharge signal PRESA are at a high level (VDD). The pairs of bit lines BL and RBL and the pairs of signal lines INBL and INRBL are therefore cut off by the switch circuit 14, but the pairs of bit lines BL and RBL and the pairs of signal lines INBL and INRBL are precharged to an intermediate potential VHF. During this period, the sense amplifier active signals SAP and SAN are both inactive.

Then, at time t21, the sense amplifier precharge signal PRESA is inactivated, and the sense amplifier active signals SAP and SAN are then activated at time t22. At time t22, the pairs of signal lines INBL and INRBL have been precharged to the same potential (intermediate potential VHF) by the sense amplifier precharge circuit 60, and ideally no sensing operations will be performed by the sense amplifier 20, despite the activation of the sense amplifier 20. However, due to the offset of the sense amplifier 20, sensing is performed at time t22, and one of the pairs of signal lines INBL and INRBL is driven at a high level while the other is driven at a low level.

Next, at time t23, equalizing signals EQ and EQB are activated. The equalizing signal EQ is a signal supplied to the gate electrode of the transistor N15, and the equalizing signal EQB is a signal supplied to the gate electrode of the transistor P6. The pairs of signal lines INBL and INRBL are thereby short circuited. That is, the pairs of signal lines INBL and INRBL are short circuited while the sense amplifier 20 is activated. Because the amplitude of the sense amplifier 20 is thus limited, potential differences will show up in the pair of signal lines INBL and INRBL according to the mismatch between the threshold voltages of the transistors that constitute the sense amplifier 20 or the mismatch of the on-current Ion, and will remain stable in that state. In this way, the potential difference ΔV appearing in the pair of signal lines INBL and INRBL is proportional to the offset voltage in the sense amplifier 20.

Next, the timing signal φ1 is activated at time t24 while the potential difference ΔV is present in the pair of signal lines INBL and INRBL. The signal line INBL is thus connected to the node A through the transistor N13, and the signal line INRBL is connected to the node B through the transistor N14. The inactivation of the timing signal φ1 at time t26 results in the storage of the cancel charge in the electrodes CE1 and CE2, respectively, of the capacitative element C1. The sense amplifier active signals SAP and SAN are then inactivated and the equalizing signals EQ and EQB are inactivated at time t27.

The sense amplifier precharge signal PRESA is then again activated at time t28. The pair of signal lines INBL and INRBL is thus again precharged to the intermediate potential VHF. When the sense amplifier precharge signal PRESA is then inactivated at time t30, the production of the cancel charge is complete. In FIG. 12, T1 represents the period during which the cancel charge is produced.

During the production of the cancel charge, the bit line precharge signal PREBL is inactivated, and a predetermined word line WL is then activated. A memory cell MC corresponding to the selected world line WL is thereby connected to the bit line BL or RBL, and the potential changes according to the stored content. In the example shown in FIG. 12, the bit line precharge signal PREBL is inactivated at time t25, and the word line WL is activated at time t29, but the timing is not limited to this option alone. The production of cancel charge and the selection of memory cell MC can thus be accomplished in parallel in the present embodiment.

When the production of the cancel charge and the reading of the memory cell MC are completed, the pass signal PASSEN is activated in the period from time t31 to t32. The pair of bit lines BL and RBL and the pair of signal lines INBL and INRBL are thereby short circuited, and the charge read from the memory cell MC is fed to the sense amplifier 20. During this period, however, the sense amplifier 20 does not perform any sensing operations because the sense amplifier active signals SAP and SAN are both inactivated. In FIG. 12, T2 represents the period during which charge is sent to the sense amplifier 20.

The timing signal φ3 is then activated at time t32. The transistors N17 and N18 that constitute the cancel charge feed circuit 50 are thereby turned on, the node B is connected to the signal line INBL, and the node A is connected to the signal line INRBL. The offset in the sense amplifier 20 is thereby cancelled. In FIG. 12, T3 represents the period during which the offset voltage is cancelled.

Subsequently activating the sense amplifier active signals SAP and SAN at time t34 causes the sense amplifier 20 to be activated and an amplification operation to be performed according to the potential difference occurring in the pair of signal lines INBL and INRBL. Because the sense amplifier 20 is activated in this way, with the offset voltage cancelled in advance, the sensing margin is dramatically increased. In FIG. 12, T4 represents the period during which sensing is performed.

When the pass signal PASSEN is then activated again at time t35, the signal amplified by the sense amplifier 20 is restored in the memory cell MC. In FIG. 12, T5 represents the period during which the restore operation is performed.

Thus, in the present embodiment, the equalizing transistors P6 and N15 are turned on while the sense amplifier 20 is activated, whereby offset voltage is produced between the pair of signal lines INBL and INRBL, and the voltage is stored in the capacitative element C1. The offset voltage in the sense amplifier 20 can therefore be nearly completely cancelled by appropriately selecting the size of the equalizing transistors P6 and N15 and the capacity of the capacitative element C1.

Because the cancel charge is also produced statically in the present embodiment, there is no need to provide the pre-discharge transistor of the first embodiment or the precharge transistor of the second embodiment. There is also no need to stringently control the timing for activating and inactivating the timing signal φ1 for the static production of cancel charge, resulting in easier design.

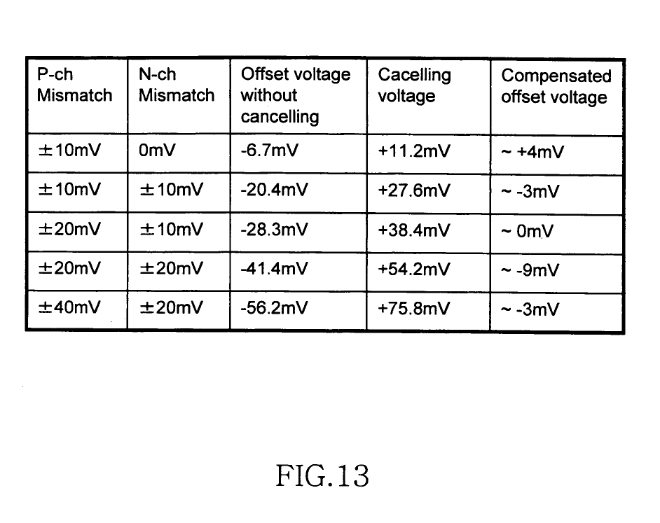

FIG. 13 comprises the simulation results showing the effects of the present embodiment. The simulation in FIG. 13 shows the values of the offset voltage prior to cancellation (Offset voltage without cancelling), the voltage provided by the cancellation operation (Cancelling voltage), and the offset voltage after cancellation (Compensated offset voltage), according to the threshold voltage difference (N−ch Mismatch) of the pull-down transistors N1 and N2 and the threshold voltage difference (P−ch Mismatch) of the pull-up transistors 21 and P2 that constitute the sense amplifier 20.

As shown in FIG. 13, the greater the threshold voltage difference, the greater the pre-cancellation offset voltage proportional thereto. However, the greater the threshold voltage difference, the greater the voltage provided by the cancellation operation in proportion to the difference. As a result, the offset voltage after cancellation is substantially close to zero, regardless of the threshold voltage difference. It may thus be seen that, according to the present embodiment, the offset voltage can be almost completely cancelled, regardless of the threshold voltage difference.

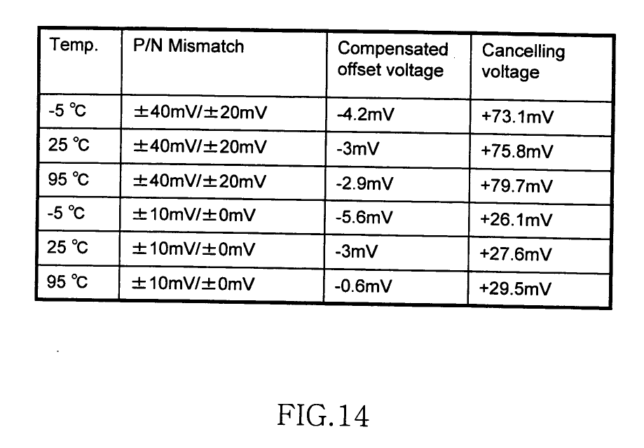

FIG. 14 comprises other simulation results showing the effect of the present embodiment. The simulation shown in FIG. 14 shows the values of the voltage provided by the cancellation operation (Cancelling voltage) and the offset voltage after cancellation (Compensated offset voltage), in cases where there are changes in both the ambient temperature (Temp.) and the threshold voltage difference of the pull-down transistors N1 and N2 and the threshold voltage difference in the pull-up transistors P1 and P2 that constitute the sense amplifier 20 (P/N Mismatch).

As shown in FIG. 14, when the threshold voltage difference is the same, the voltage provided by the cancellation operation was greater the higher the ambient temperature, and as a result, the offset voltage after cancellation was substantially close to zero, regardless of the threshold voltage difference and ambient temperature. It may thus be seen that, according to the present embodiment, the offset voltage can be almost completely cancelled, regardless of the change in ambient temperature.

It is apparent that the present invention is not limited to the above embodiments, but may be modified and changed without departing from the scope and spirit of the invention.

For example, in the embodiments described above, the example was of the present invention in a DRAM application, but suitable applications for the present invention are not limited to this option alone. Other semiconductor memory (SRAM, PRAM, flash memory, and the like) applications are also possible. Suitable applications for the present invention are also not limited to semiconductor memory, and can also include any semiconductor device equipped with a sense amplifier.

What is claimed is:

1. A semiconductor device comprising:
first and second signal lines;
a sense amplifier amplifying a potential difference occurring in the first and second signal lines;
a cancel charge generator circuit producing cancel charge that corresponds to an offset voltage in the sense amplifier;
a cancel charge storage circuit storing the cancel charge; and
a cancel charge feed circuit feeding the cancel charge that has been stored in the cancel charge storage circuit to the first and second signal lines to cancel the offset voltage.

2. The semiconductor device as claimed in claim 1, wherein,
the sense amplifier includes a first drive circuit unit driving the first signal line and a second drive circuit unit driving the second signal line, and
the cancel charge generator circuit detects the offset voltage on the basis of difference in ability between the first drive circuit unit and second drive circuit unit to produce the cancel charge based on the offset voltage.

3. The semiconductor device as claimed in claim 2, wherein,
the cancel charge includes a first cancel charge based on at least the ability of the first drive circuit unit, and a second cancel charge based on at least the ability of the second drive circuit, and
the cancel charge storage circuit includes a first electrode storing the first cancel charge and a second electrode storing the second cancel charge.

4. The semiconductor device as claimed in claim 3, wherein the cancel charge feed circuit feeds the first cancel charge stored in the first electrode to the second signal line, and feeds the second cancel charge stored in the second electrode to the first signal line.

5. The semiconductor device as claimed in claim 4, wherein,
the first drive circuit unit of the sense amplifier has a first pull-up transistor pulling up the first signal line, and a first pull-down transistor pulling down the first signal line,
the second drive circuit unit of the sense amplifier has a second pull-up transistor pulling up the second signal line, and a second pull-down transistor pulling down the second signal line, and
the first pull-up transistor and the first pull-down transistor are cross coupled with the second pull-up transistor and the second pull-down transistor.

6. The semiconductor device as claimed in claim 5, wherein,
the cancel charge generator circuit includes equalizing transistor short-circuiting the first signal line and the second signal line, a first cancel charge input transistor connecting the first signal line and the first electrode, and a second cancel charge input transistor connecting the second signal line and the second electrode, and
the cancel charge feed circuit includes a first cancel charge output transistor connecting the first signal line and the second electrode, and a second cancel charge output transistor connecting the second signal line and the first electrode.

7. The semiconductor device as claimed in claim 6, further comprising a control circuit controlling an operation of at least the sense amplifier, the cancel charge generator circuit, and the cancel charge feed circuit,
wherein the control circuit turns on the equalizing transistor to produce the first and second cancel charges in the first and second signal lines, respectively, turns on the first and second cancel charge input transistors to store the first and second cancel charges in the first and second electrodes, respectively, and turns on the first and second cancel charge output transistors to feed the first and second cancel charges to the second and first signal lines, respectively.

8. The semiconductor device as claimed in claim 7, wherein,
the cancel charge generator circuit further includes a first pre-discharge transistor pre-discharging the first signal line and a second pre-discharge transistor pre-discharging the second signal line, and
the control circuit turns on the equalizing transistor after the first and second signal lines have been temporarily discharged by the first and second pre-discharge transistors while operating voltage is supplied to the first and second pull-up transistors without supplying an operating voltage to the first and second pull-down transistors included in the sense amplifier, so that the first and second signal lines are pulled up at a rate according to the ability of the first and second pull-up transistors, respectively, and the first and second cancel charge input transistors are turned from on to off while a potential difference is produced in the first and second signal lines, so that the first and second cancel charges are stored in the first and second electrodes, respectively.

9. The semiconductor device as claimed in claim 7, wherein,
the cancel charge generator circuit further includes a first precharge transistor precharging the first signal line and a second precharge transistor precharging the second signal line, and the control circuit turns on the equalizing transistor after the first and second signal lines have been temporarily precharged by the first and second precharge transistors while operating voltage is supplied to the first and second pull-down transistors without supplying an operating voltage to the first and second pull-up transistors included in the sense amplifier, so that the first and second signal lines are pulled down at a rate according to the ability of the first and second pull-down transistors, respectively, and the first and second cancel charge input transistors are turned from on to off while a potential difference is produced in the first and second signal lines, so that the first and second cancel charges are stored in the first and second electrodes, respectively.

10. The semiconductor device as claimed in claim 7, wherein the control circuit turns on the equalizing transistor in a state in which the sense amplifier is activated.

11. The semiconductor device as claimed in claim 7, further comprising:
first and second bit lines connected via a switch circuit to the first and second signal lines, respectively;
a plurality of word lines intersecting the first and second bit lines; and
a plurality of memory cells arranged at intersections of the plurality of word lines and the first and second bit lines, wherein,
before the switch circuit is activated, the control circuit activates any one of the plurality of word lines, and turns on the equalizing transistor and the first and second cancel charge input transistors.

12. The semiconductor device as claimed in claim 11, wherein the control circuit turns on the first and second cancel charge output transistors after the switch circuit is activated.

13. A method for cancelling offset voltage of a sense amplifier that amplifies a potential difference occurring in first and second signal lines, comprising:
producing cancel charge according to the offset voltage in the sense amplifier to store the cancel charge; and
feeding the stored cancel charge to the first and second signal lines to cancel the offset voltage.

14. The method as claimed in claim 13, wherein,
first and second cancel charges are produced for the first and second signal lines, respectively, in the producing cancel charge, and
the first and second cancel charges are fed to the second and first signal lines, respectively, in the feeding the stored cancel charge.

15. The method as claimed in claim 14, wherein the first signal line and second signal line are short circuited in the producing cancel charge.

16. The method as claimed in claim 15, wherein the first and second signal lines are temporarily discharged or precharged before being short circuited.

17. The method as claimed in claim 15, wherein the first signal line and the second signal line are short circuited in a state in which the sense amplifier is activated in the producing cancel charge.

18. The method as claimed in claim 13, wherein,
the first and second signal lines are connected through a switch circuit to first and second bit lines, respectively, and
the producing cancel charge is performed in a state in which the switch circuit is off.

19. The method as claimed in claim 18, wherein the feeding the stored cancel charge is performed in a state in which the switch circuit is on.
